(19) United States
(12) Patent Application Publication
(10) Pub. No.: US 2025/0107375 A1
(43) Pub. Date: Mar. 27, 2025

(54) DISPLAY PANEL AND FABRICATION METHOD THEREOF, AND DISPLAY DEVICE

(71) Applicant: Hubei Yangtze Industrial Innovation Center of Advanced Display Co., LTD., Wuhan (CN)

(72) Inventor: Meihong WANG, Wuhan (CN)

(21) Appl. No.: 18/613,169

(22) Filed: Mar. 22, 2024

(30) Foreign Application Priority Data
Sep. 21, 2023 (CN) 202311231258.8

(51) Int. Cl. H10K 59/131; H10K 59/12

(52) U.S. Cl. CPC H10K 59/1315; H10K 59/1201

(57) ABSTRACT

A display panel and its fabrication method, and a display device are provided. The display panel includes a display region and a virtual pixel region around the display region. The display region includes display sub-pixels, and a plurality of signal transmission lines are disposed in the display region for connecting pixel circuits. The virtual pixel region includes virtual sub-pixels and a plurality of virtual signal lines connected to the virtual sub-pixels. At least a portion of the plurality of the virtual signal lines is connected to the plurality of signal transmission lines.

### CROSS-REFERENCE TO RELATED APPLICATION

This application claims the priority of Chinese Patent Application No. 202311231258.8, filed on Sep. 21, 2023, the content of which is incorporated herein by reference in its entirety.

### TECHNICAL FIELD

The present disclosure generally relates to the field of display technology and, more particularly, relates to a display panel and its fabrication method, and a display device.

### BACKGROUND

With the continuous development of display technology, screen sizes of display devices are getting larger and larger.

As screen sizes become larger and larger, screen uniformity requirements become higher and higher. However, in display panels in existing technology, because of high voltage drops on corresponding signal transmission lines, the same type of signal voltage received by each pixel circuit is greatly different. Therefore, it is difficult to meet the expected requirements for screen uniformity.

### SUMMARY

One aspect of the present disclosure provides a display panel. The display panel includes: a display region and a virtual pixel region around the display region. The display region includes display sub-pixels, and a plurality of signal transmission lines are disposed in the display region for connecting pixel circuits. The virtual pixel region includes virtual sub-pixels and a plurality of virtual signal lines connected to the virtual sub-pixels. At least a portion of the plurality of the virtual signal lines is connected to the plurality of signal transmission lines.

Another aspect of the present disclosure provides a fabrication method of a display panel. The method includes: providing a substrate including a first region corresponds to a display region of the display panel and a second region corresponds to a virtual pixel region of the display panel; forming a composite dielectric layer on a side of the substrate; and forming signal transmission lines and virtual signal lines on a side of the composite dielectric layer away from the substrate. Orthographic projections of the signal transmission lines on the substrate overlap with the first region and extend to the second region. Orthographic projections of the virtual signal lines on the substrate are located in the second region. At least part of the virtual signal lines is connected to the signal transmission lines. The signal transmission lines include signal lines for connecting pixel circuits.

Another aspect of the present disclosure provides a display device. The display device includes a display panel. The display panel includes: a display region and a virtual pixel region around the display region. The display region includes display sub-pixels, and a plurality of signal transmission lines are disposed in the display region for connecting pixel circuits. The virtual pixel region includes virtual sub-pixels and a plurality of virtual signal lines connected to the virtual sub-pixels. At least a portion of the plurality of the virtual signal lines is connected to the plurality of signal transmission lines.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a planar structure of a display panel;

FIG. 2 illustrates a planar structure of an exemplary display panel consistent with various disclosed embodiments in the present disclosure;

FIG. 3 illustrates a planar structure of another exemplary display panel consistent with various disclosed embodiments in the present disclosure;

FIG. 4 illustrates an exemplary pixel circuit consistent with various disclosed embodiments in the present disclosure;

FIG. 5 illustrates a planar structure of another exemplary display panel consistent with various disclosed embodiments in the present disclosure;

FIG. 6 illustrates a cross-section view of another exemplary display panel consistent with various disclosed embodiments in the present disclosure;

FIG. 7 illustrates a planar structure of another exemplary display panel consistent with various disclosed embodiments in the present disclosure;

FIG. 8 illustrates a planar structure of another exemplary display panel consistent with various disclosed embodiments in the present disclosure;

FIG. 9 illustrates a cross-sectional view of another exemplary display panel consistent with various disclosed embodiments in the present disclosure;

FIG. 10 illustrates a planar structure of another exemplary display panel, consistent with various disclosed embodiments in the present disclosure;

FIG. 11 illustrates a cross-sectional view of another exemplary display panel consistent with various disclosed embodiments in the present disclosure;

FIG. 12 illustrates a planar structure of another exemplary display panel consistent with various disclosed embodiments in the present disclosure;

FIG. 13 illustrates a planar structure of another exemplary display panel consistent with various disclosed embodiments in the present disclosure;

FIG. 14 illustrates a planar structure of another display panel;

FIG. 15 illustrates an exemplary fabrication method of a display panel consistent with various disclosed embodiments in the present disclosure;

FIG. 16 illustrates an exemplary substrate consistent with various disclosed embodiments in the present disclosure;

FIG. 17 illustrates a cross-sectional view of a structure corresponding to S1502 in an exemplary fabrication method of a display panel consistent with various disclosed embodiments in the present disclosure; and

FIG. 18 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region.

In the present disclosure, the term “electrical connection” refers to that two components are directly electrically connected with each other, or the two components are electrically connected via one or more other components.

An electronic or electrical device and/or any other related device or component according to embodiments of the present disclosure (e.g., a display device including a display panel and a display panel driver, where the display panel driver further includes a drive controller, a gate driver, a gamma reference voltage generator, a data driver, or a transmit driver) may be implemented using any suitable hardware, firmware (such as an application specific integrated circuit), software, or a combination of software, firmware and hardware. For example, the various components of these devices may be formed on one integrated circuit (IC) chip or on separate IC chips. Additionally, the various components of these devices may be implemented on flexible printed circuit films, tape carrier packages (TCP), printed circuit boards (PCB), or formed on a substrate. Additionally, various components of these devices may be implemented as processes or threads in one or more computing devices and running on one or more processors to execute computer program instructions and/or interact with other system components, to perform various functions provided by the present disclosure. The computer program instructions may be stored in a memory, and the memory may be implemented in a computing device using standard storage devices, such as random access memory (RAM). The computer program instructions may also be stored on other non-transitory computer-readable media (such as CD-ROM, flash drive, etc.). Furthermore, those skilled in the art will recognize that the functionality of various computing devices may be combined or integrated into a single computing device, or the functionality of a particular computing device may be distributed among one or more or other computing devices without departing from the spirit and scope of the present disclosure.

Exemplary embodiments of a display module and a display device including a display module have been specifically described herein, many modifications and changes may be made and will be apparent to those skilled in the art. Accordingly, it will be understood that display modules constructed in accordance with the principles of the present disclosure and display devices including the display modules may be implemented other than what is specifically described herein. The present disclosure is also limited to claims and their equivalents.

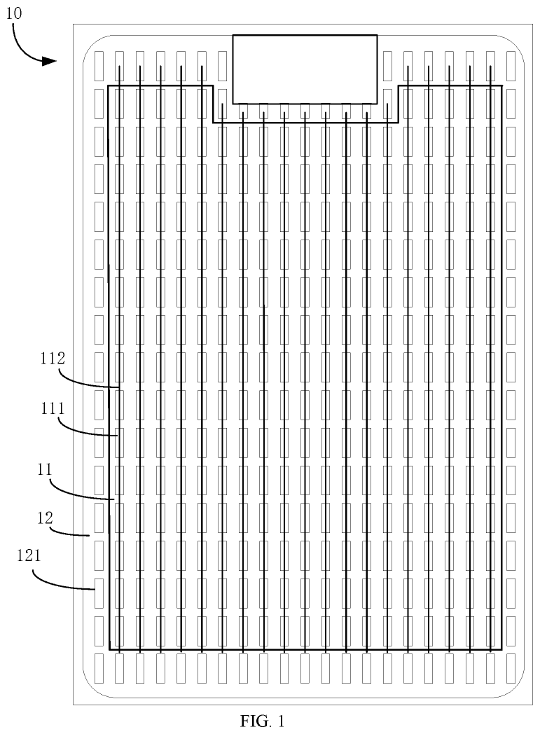

FIG. 1 illustrates a planar structure of a display panel in existing technology. As shown in FIG. 1, the display panel 10 includes a display region 11 and a virtual pixel region 12. In FIG. 1, signal transmission lines 12 extending along a first direction are disposed in the display region 11. In the display panel 10, signals are transmitted to display sub-pixels 111 in the display region 11 through the signal transmission lines 12. For example, first power signal lines (PVDD signal lines) in the display region 11 transmit a first power signal (a PVDD signal) to the display sub-pixels 111 in the display region 11. However, the signal transmission lines 112 have resistance, and the transmission of signals on the signal transmission lines 112 results in a large voltage drop. Therefore, a same type of signals received by each pixel circuit has a large voltage difference, and the screen uniformity cannot meet expected requirements.

Based on FIG. 1, it could be understood that, in the display panel 10 in existing technology, the voltage drop on the signal transmission lines 112 is large and a same type of signals received by each pixel circuit has a large voltage difference. Therefore, the screen uniformity cannot meet expected requirements.

To at least partially alleviate the above problems, by connecting the signal transmission lines and other signal lines in parallel, the parallel transmission lines formed by connecting the signal transmission lines and other signal lines in parallel may have a lower resistance compared to the signal transmission lines, and the voltage drop of the signal transmission lines may be reduced. The present disclosure provides a display panel. The display panel may include a display region and a virtual pixel region surrounding the display region. The display region may include display sub-pixels and a plurality of signal transmission lines may be disposed in the display region. The plurality of signal transmission lines may include signal lines for electrically connecting pixel circuits. The virtual pixel region may include virtual sub-pixels and a plurality of virtual signal lines connected to the virtual sub-pixels. At least a part of the plurality of virtual signal lines may be connected to the plurality of signal transmission lines.

In the present disclosure, at least a part of the plurality of virtual signal lines may be connected to the plurality of signal transmission lines. Therefore, at least a part of the plurality of virtual signal lines may be connected with the plurality of signal transmission lines in the display region in parallel. Compared to the plurality of signal transmission lines, parallel transmission lines formed by connecting the plurality of signal transmission lines and the part of the plurality of virtual signal lines in parallel may have a lower resistance, and the voltage drop of the signal transmission lines may be reduced. Therefore, the voltage uniformity of the plurality of signal transmission lines may be maintained and the display uniformity of the display panel may be improved.

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted. Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

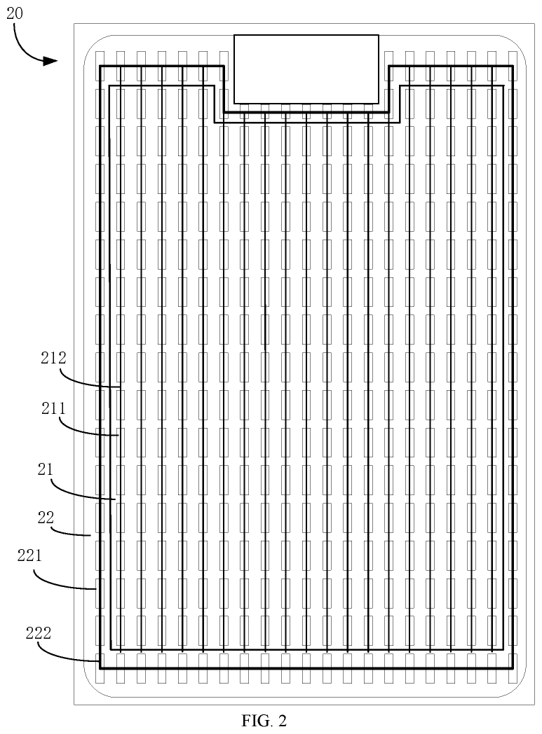

One embodiment of the present disclosure provides a display panel. FIG. 2 illustrates a planar structure of the display panel 20 provided by the present embodiment. As shown in FIG. 2, the display panel 20 may include a display region 21 and a virtual pixel region 22. The virtual pixel region 22 may be located around the display region 21. The display region 21 may include display sub-pixels 211, and a plurality of signal transmission lines 212 may be disposed in the display region 21. The plurality of signal transmission lines 212 may include signal lines for connecting pixel circuits. The virtual pixel region 22 may include virtual sub-pixels 221 and a plurality of virtual signal lines 222 connected to the virtual sub-pixels 221. At least a part of the plurality of virtual signal lines 222 may be connected to the plurality of signal transmission lines 212.

In one embodiment, the plurality of signal transmission lines 212 and the part of the plurality of virtual signal lines 222 connected to the plurality of signal transmission lines 212 may be located in different layers. Therefore, the part of the plurality of virtual signal lines 222 may be connected to the plurality of signal transmission lines 212 via through holes. The number of the through holes may be one or two, and the plurality of signal transmission lines 212 may be connected to the part of the plurality of virtual signal lines 222 every other rows or every multiple rows via through holes.

In one embodiment, the plurality of signal transmission lines 212 may be first power signal lines which may be used to transmit first power signals. In some other embodiment, the plurality of signal transmission lines 212 may also be initialization signal lines which may be used to transmit the initialization signals. The plurality of signal transmission lines 212 may be connected to the plurality of virtual signal lines 222 and then arranged in a circle around the display region 21. In some other embodiment, the plurality of signal transmission lines 212 may be straight lines extending along a target direction, and the target direction may include at least one of a first direction or a second direction.

When forming the display panel 20, the virtual sub-pixels 221 and the plurality of virtual signal lines 222 may be formed in the virtual pixel region 22. Generally, the virtual sub-pixels 221 may not emit light, and the plurality of virtual signal lines 222 may not need to transmit corresponding signals to the virtual sub-pixels 221. Based on this, by connecting at least a part of the plurality of virtual signal lines 222 to the plurality of signal transmission lines 212, the signals on the plurality of signal transmission lines 212 may be transmitted to the plurality of virtual signal lines 222, such that at least a part of the plurality of virtual signal lines 222 may be connected in parallel with the plurality of signal transmission lines 212 in the display region 21. Through the parallel connection, the voltage drop of the plurality of signal transmission lines 212 may be reduced, improving the voltage uniformity of the signals transmitted by the plurality of signal transmission lines 212 to each display sub-pixel 211 and improving the display uniformity of the display panel 20.

In the present embodiment, the display panel 20 may include the display region 21 and the virtual pixel region 22. The display region 21 may include the display sub-pixels 211, and the plurality of signal transmission lines 212 may be disposed in the display region 21. The virtual pixel region 22 may include the virtual sub-pixels 221 and the plurality of virtual signal lines 222 connected to the virtual sub-pixels 221. At least a part of the plurality of virtual signal lines 222 may be connected to the plurality of signal transmission lines 212. Therefore, at least a part of the plurality of virtual signal lines 222 and the plurality of signal transmission lines 212 may be connected in parallel. Compared to the plurality of signal transmission lines 212, parallel transmission lines formed by the plurality of virtual signal lines 222 and the plurality of signal transmission lines 212 may have a lower resistance. Therefore, the voltage drop of the plurality of signal transmission lines 212 may be reduced, improving the voltage uniformity of the plurality of signal transmission lines 212 and improving the display uniformity of the display panel 20.

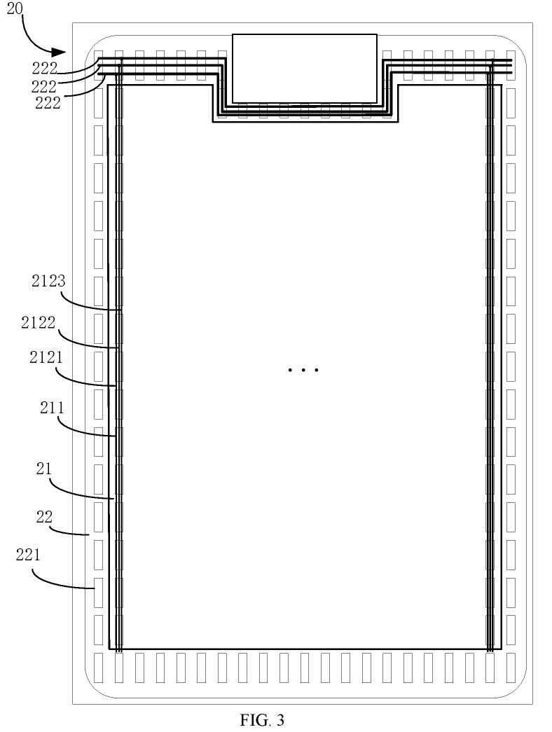

FIG. 3 illustrates a planar structure of a display panel provided by another embodiment of the present disclosure. As shown in FIG. 3, in the present embodiment, types of the plurality of signal transmission lines 212 may include at least one of first power signal lines 2121, second power signal lines 2122, or initialization signal lines 2123. The first power signal lines 2121 may be used to output the first power signal PVDD, the second power signal lines 2122 may be used to output the second power signal PVEE, and the initialization signal lines 2123 may be used to output the initialization signal Vref.

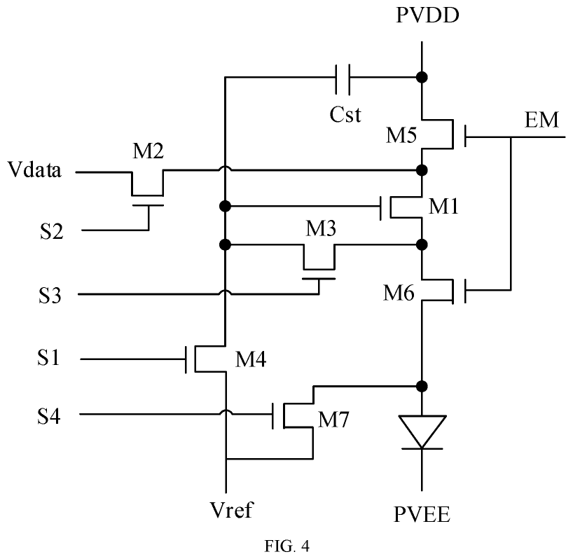

To further explain the principle of the above embodiment, a 7T1C pixel circuit will be used as an example in the following. FIG. 4 is a schematic structural diagram of a pixel circuit provided by one embodiment of the present disclosure. As shown in FIG. 4, the 7T1C pixel circuit includes a driving transistor M1, a storage capacitor Cst, a data writing transistor M2, a threshold compensation transistor M3, a first initialization transistor M4, a second initialization transistor M7, a first light emission control transistor M5, and a second light emission control transistor M6.

A first terminal of the first light emission control transistor M5 may be used to receive the first power signal PVDD. A first terminal of the driving transistor M1 and a first terminal of the storage capacitor Cst may be respectively connected to a second terminal of the first light emission control transistor M5. A second terminal of the driving transistor M1 may be respectively connected to a first terminal of the threshold compensation transistor M3 and a second terminal of the second light emitting control transistor M6. A second terminal of the threshold compensation transistor M3 may be respectively connected to a second terminal of the storage capacitor Cst and a gate terminal of the driving transistor M1. A first terminal of the first initialization transistor M4 may be used to receive the initialization signal Vref. A second terminal of the first initialization transistor M4 may be connected to the second terminal of the storage capacitor Cst and the gate terminal of the driving transistor M1 respectively. The first terminal of the second initialization transistor M7 may be used to receive the initialization signal Vref, and the second terminal of the second initialization transistor M7 may be connected to an anode of a corresponding light emission element.

In an initialization phase, the first initialization transistor M4 and the second initialization transistor M7 may be turned on respectively, and the initialization signal Vref may be written into the second terminal of the storage capacitor Cst and the gate terminal of the driving transistor M1 through the first initialization transistor M4, to initialize the second terminal of the storage capacitor Cst and the gate terminal of the driving transistor M1. Further, the initialization signal Vref may be written into the anode of the light emission element through the second initialization transistor M7 to initialize the anode of the light emission element. The consistency of the initialization signal Vref received by each pixel circuit may significantly affect the initialization effect of each pixel circuit, and reducing the voltage drop of the initialization signal lines 2123 may improve the consistency of the initialization signal Vref output to each pixel circuit, thereby improving initialization effect on each pixel circuit and improving display uniformity. Therefore, the plurality of signal transmission lines 212 may include the initialization signal lines 2123.

In a light emission phase, the first light emission control transistor M5 and the second light emission control transistor M6 may be turned on. The anode of the light emission element may receive the first power signal PVDD, and the cathode 25 of the light emission device may receive the second power signal PVEE. The first power signal PVDD and the second power signal PVEE may affect the luminous brightness of the light emission element. Therefore, the consistency of the first power signal PVDD and the second power signal PVEE may affect the consistency of the luminous brightness of each light emission element, which in turn affects display uniformity. Reducing the voltage drop of the first power signal lines 2121 may be beneficial to improving the consistency of the first power signal PVDD output to each pixel circuit, and reducing the voltage drop of the second power signal lines 2122 may be beneficial to improving the consistency of the first power signal PVDD output to each pixel circuit. Therefore, the plurality of signal transmission line 212 may include at least one of the initialization signal lines 2123, the first power signal lines 2121, or the second power signal lines 2122.

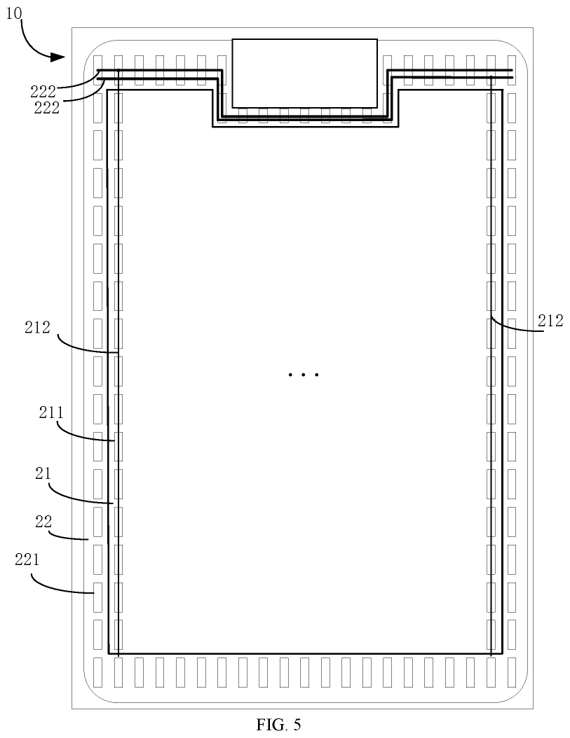

FIG. 5 illustrates a planar structure of a display panel provided by another embodiment of the present disclosure. As shown in FIG. 3, in the present embodiment, the plurality of virtual signal lines 222 in the virtual display region 22 may be connected to signal transmission lines 212 of same types among the plurality of signal transmission lines 212 respectively. In some embodiments, one of the plurality of virtual signal lines 222 in the virtual display region 22 may be connected to multiple signal transmission lines 212 of a same type among the plurality of signal transmission lines 212.

The virtual pixel region 22 may include a variety of different types of signal lines, such as first virtual power supply signal lines and virtual initialization signal lines 2123, that is, the first power supply signal lines 2121 and the initialization signal lines 2123 located in the virtual pixel region 22. Different types of signal lines in the virtual pixel region 22 may be connected to the same type of signal transmission lines 212. For example, the first power signal lines 2121 may be connected to the first virtual power signal lines or the virtual initialization signal lines 2123. For example, in one embodiment, the plurality of signal transmission lines 212 may be the plurality of first power signal lines 2121, the plurality of first power signal lines 2121 may be connected to a plurality of virtual signal lines 222 of the same type in a one-to-one correspondence, or may be connected to a plurality of virtual signal lines 222 of different types. For example, in one embodiment, the plurality of first power signal lines 2121 may be connected to the plurality of first virtual power signal lines in a one-to-one correspondence, or may be connected to the plurality of virtual initialization signal lines 2123 in a one-to-one correspondence. For another example, a part of the plurality of first power signal lines 2121 may be connected to the plurality of first virtual power signal lines in a one-to-one correspondence, and another part of the plurality of first power signal lines 2121 may be connected to the plurality of virtual initialization signal lines 2123 in a one-to-one correspondence.

The plurality of virtual signal lines 222 in the virtual pixel region 22 may be connected to the plurality of signal transmission line 212 of same type respectively, such that there may be no need to distinguish the types of the plurality of virtual signal lines 222 in the virtual pixel region 22, improving the connection flexibility of the plurality of signal transmission line s212 and the plurality of virtual signal lines 222. Therefore, the manufacturing difficulty of the display panel 20 may be reduced.

In one embodiment shown in FIG. 3, the plurality of virtual signal lines 222 in the virtual pixel region 22 may be respectively connected to different types of signal transmission lines 212. It should be noted that the plurality of virtual signal lines 222 in the virtual pixel region 22 may be connected to different types of signal transmission lines 212 in a one-to-one correspondence, and different types of signal transmission lines 212 cannot be connected to one same virtual signal line 222.

The plurality of virtual signal lines 222 in the virtual pixel region 22 may be respectively connected to different types of signal transmission lines 212, such that the different types of signal transmission lines 212 may be respectively connected in parallel to the plurality of virtual signal lines 222. In one embodiment, preferably, the plurality of signal transmission lines 212 may be connected to the plurality of virtual signal lines 222 of the same type in the virtual pixel region, thereby reducing the number of through holes. For example, the first power signal lines 2121 may be correspondingly connected to the first virtual power signal lines, and the initialization signal lines 2123 may be correspondingly connected to the virtual initialization signal lines 2123. In another embodiment, the first power supply signal lines 2121 may also be connected to the virtual initialization signal lines 2123, and the initialization signal lines 2123 may be connected to the first virtual power signal lines. Therefore, the voltage drops of the plurality of signal transmission lines 212 of different types may be reduced at the same time, which is beneficial to improving the consistency of signals of different types and further improving display uniformity.

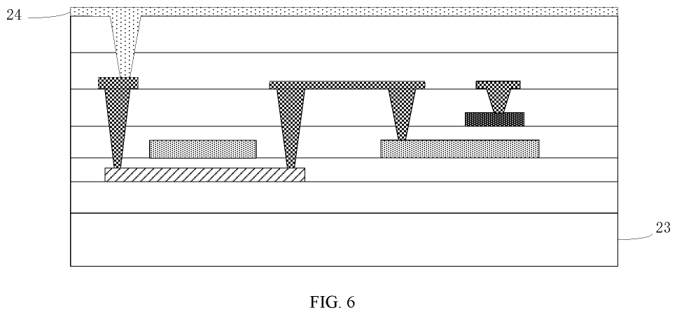

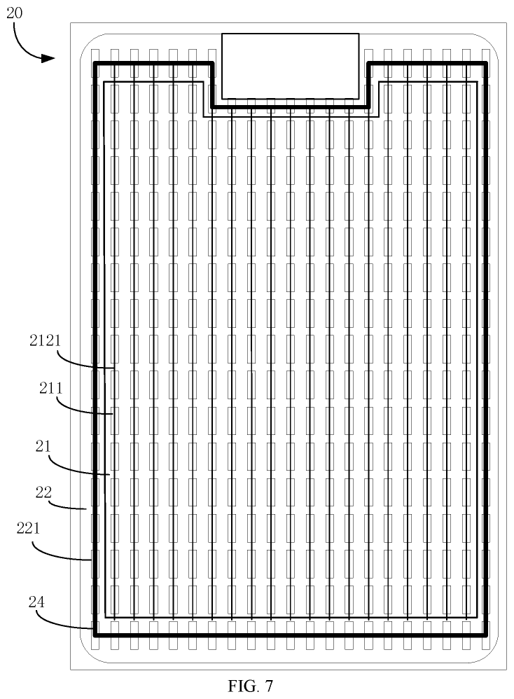

In another embodiment shown in FIG. 6 which is a cross-sectional view of a display panel provided by the present embodiment and FIG. 7 which is a planar structure of the display panel provided by the present embodiment, the display panel 20 may further include a substrate 23 and an anode layer 24 on one side of the substrate. The anode layer 24 may include anodes of the virtual sub-pixels 221, and at least a part of the anodes of the virtual sub-pixels 221 may be connected to the first power signal lines 2121 to receive the first power signal PVDD transmitted by the first power signal lines 2121.

Optionally, in one embodiment, the substrate 23 may be a flexible substrate or a rigid substrate, which is not limited in the present disclosure.

The anode layer 24 may be a conductive layer and may be able to transmit signals. Therefore, by connecting at least a part of the anodes of the virtual sub-pixels 221 to the first power signal lines 2121, the anodes of the virtual sub-pixels 221 may be used as a signal transmission carrier, that is, the anodes of the virtual sub-pixels 221 may be used as the virtual signal lines 222, such that the first power signal lines 2121 are connected in parallel with the anodes of the virtual sub-pixels 221. Correspondingly, the voltage drop on the first power signal lines 2121 may be reduced, improving the voltage uniformity of the first power signal PVDD output to each pixel circuit, thereby improving display uniformity.

In one embodiment shown in FIG. 7, the anode of each virtual sub-pixel 221 may be connected to each other.

By connecting the anode of each virtual sub-pixel 221 to each other, the cross-sectional region of the anode layer may be increased. Since the resistance of a conductor is inversely proportional to the cross-sectional region of the conductor, in the present embodiment, the resistance of the anode layer may be reduced, thereby reducing the resistance of the parallel line formed by the first power signal lines 2121 and the anode layer. Also, there may be no need to divide the anode layer into anodes for each virtual sub-pixel 221, which is beneficial to reducing the process difficulty of the display panel.

When the anodes of each virtual sub-pixel 221 is connected to each other, since each virtual sub-pixel 221 is arranged around the display region 21, the anode of each virtual sub-pixel 221 may be connected to form an annular anode layer 24 surrounding the display region 21 and the annular anode layer 24 may be connected to the first power signal lines 2121, such that the first power signal lines 2121 are connected in parallel with the annular anode layer 24 to further reduce the voltage drop on the first power signal lines 2121 and increase the voltage uniformity of the first power signal PVDD output to each pixel circuit. The display uniformity may be improved.

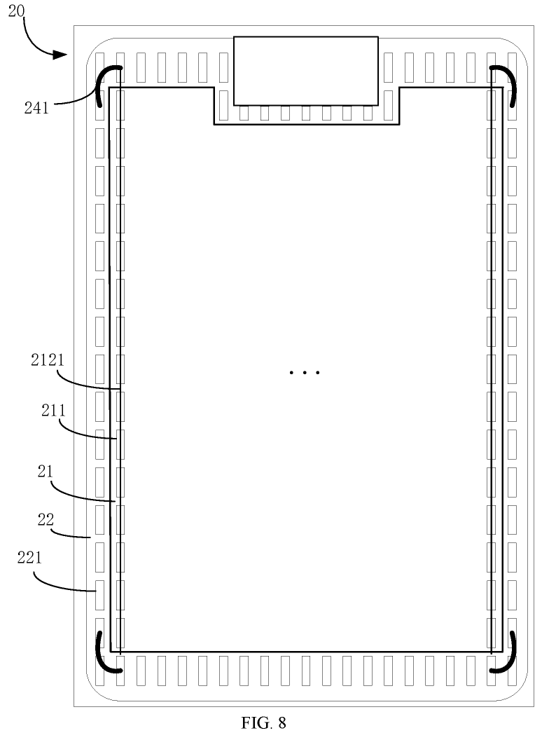

In another embodiment shown in FIG. 8 which is a planar structure of another display panel provided by the present embodiment, the virtual pixel region 22 may include a plurality of irregular-shaped regions. The anode layer 24 may include an irregular-shaped sub-anode layer 241 located in each irregular-shaped region. One irregular-shaped sub-anode layer 241 may include an anode of one corresponding virtual sub-pixel 221 in one corresponding irregular-shaped region. The irregular-shaped sub-anode layers 241 may be connected to the first power signal lines 2121 for receiving the first power signal PVDD transmitted by the first power signal lines 2121.

In one embodiment, the shape of the display panel 20 may be a rectangle, and the plurality of irregular-shaped regions may be four corner regions of the display panel 20.

Since the irregular-shaped sub-anode layers 241 includes the anodes of the corresponding virtual sub-pixels 221 in the corresponding irregular-shaped regions and may be connected to the first power signal lines 2121, the irregular-shaped sub-anode layers 241 may be connected in parallel with the first power signal lines 2121. By connecting the irregular-shaped sub-anode layers 241 in parallel with the first power signal lines 2121, the voltage drop on the first power signal lines 2121 may be reduced, the voltage uniformity of the first power signal PVDD output to each pixel circuit and the display uniformity may be improved.

Further, the plurality of irregular-shaped regions of the virtual pixel region 22 may have free space, and forming the irregular-shaped sub-anode layers 241 in the free region may not cause the change of the size of the display panel 20.

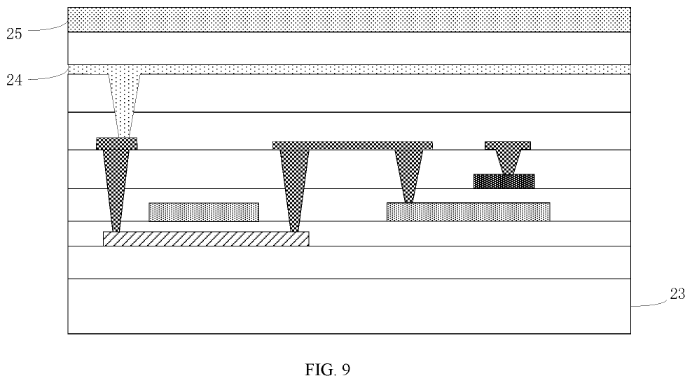

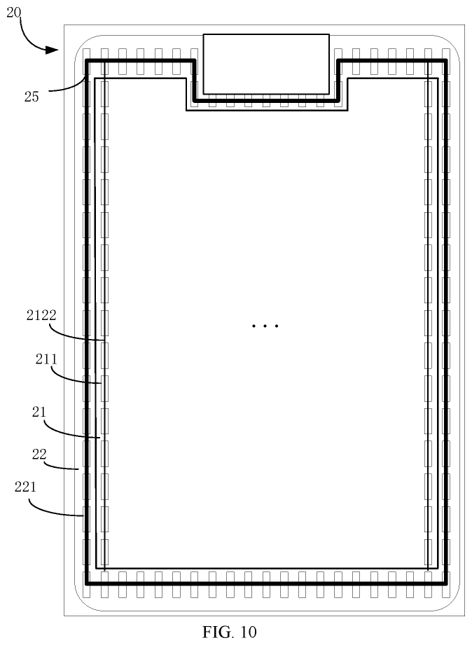

In another embodiment shown in FIG. 9 which is a cross-sectional view of a display panel provided by the present embodiment and FIG. 10 which is a planar structure of the display panel provided by the present embodiment, the display panel 20 may further include the substrate 23 and a cathode layer 25 on one side of the substrate. The cathode layer 25 may include cathodes of the virtual sub-pixels 221, and at least a part of the cathodes of the virtual sub-pixels 221 may be connected to the second power signal lines 2122 to receive the second power signal PVEE transmitted by the second power signal lines 2122.

The cathode layer 25 may be a conductive layer and may be able to transmit signals. Therefore, by connecting at least a part of the cathodes of the virtual sub-pixels 221 to the second power signal lines 2122, the cathodes of the virtual sub-pixels 221 may be used as a signal transmission carrier, that is, the cathodes of the virtual sub-pixels 221 may be used as the virtual signal lines 222, such that the second power signal lines 2122 are connected in parallel with the cathodes of the virtual sub-pixels 221. Correspondingly, the voltage drop on the second power signal lines 2122 may be reduced, improving the voltage uniformity of the second power signal PVEE output to each pixel circuit, thereby improving display uniformity.

In one embodiment shown in FIG. 9, the display panel 20 may include the substrate 23, and the virtual signal lines 222 and the virtual sub-pixels 221 may be located on a same side of the substrate 23, and between the anode layer 24 and the substrate 23. As shown in FIG. 2, a width of an orthographic projection of one virtual sub-pixel 221 on the substrate 23 may be larger than or equal to a width of an orthographic projection of one corresponding virtual signal line 222 on the substrate 23.

For example, in one embodiment, a width of an orthographic projection of one virtual sub-pixel 221 on the substrate 23 may be equal to a width of an orthographic projection of one corresponding virtual signal line 222 on the substrate 23. Therefore, a cross section of the virtual signal line 222 may have a relatively large region. Since a resistance of a conductor is inversely proportional to a cross section of the conductor, by increasing the width of the virtual signal line 222, the resistance of the virtual signal line 222 may be reduced, to reduce the voltage drop on the virtual signal line 222 and improve the voltage uniformity of the virtual signal line 222.

Since a width of an orthographic projection of one virtual sub-pixel 221 on the substrate 23 may be equal to a width of an orthographic projection of one corresponding virtual signal line 222 on the substrate 23, a range covered by the virtual signal line 222 may not be larger than a range covered by the virtual sub-pixel 221. Therefore, the virtual signal line 222 may be located within the range covered by the virtual sub-pixel 221. That is, the orthographic projection of the virtual sub-pixel 221 on the substrate 23 may cover the orthographic projection of the corresponding virtual signal line 222 on the substrate 23, and there may be no need to reserve extra wiring space in the horizontal direction for the virtual signal line 222 to prevent the horizontal size of the virtual pixel region 22 from being to large.

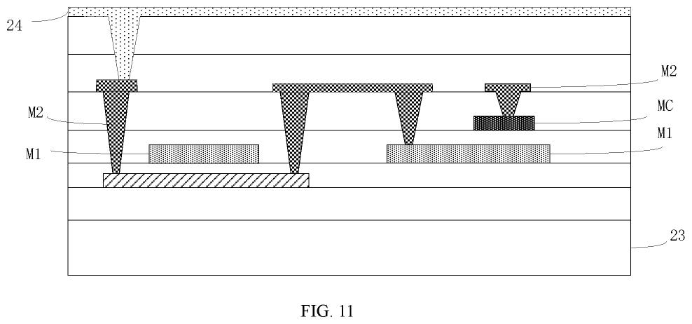

In another embodiment shown in FIG. 11 which is a cross-sectional view of a display panel provided by the present embodiment, the display panel 20 may further include the substrate 23, a first metal layer M1, a second metal layer MC, and a third metal layer M3. The first metal layer M1, the second metal layer MC, and the third metal layer M3 may be away from the substrate 23 sequentially. The initialization signal lines 2123 may be located on the second metal layer MC. One virtual sub-pixel 221 may include a signal receiving layer located in the second metal layer MC. Signal receiving layers of at least a part of the virtual sub-pixels 221 may be connected to the initialization signal lines 2123 to receive initialization signals Vref transmitted by the initialization signal lines 2123.

The pixel circuit in this embodiment may be the 7T1C pixel circuit in the previous embodiments. For example, as shown in FIG. 4 and FIG. 11, when the pixel circuit is the 7T1C pixel circuit of the previous embodiment, the gate of the driving transistor M1 may be located in the first metal layer M1, the first electrode plate of the storage capacitor Cst may be located in the first metal layer M1, and the second electrode plate of the storage capacitor Cst may be located in the second metal layer MC. The first electrode plate and the second electrode plate may overlap in a direction perpendicular to the plane where the substrate 23 is located.

The first electrode plate of the storage capacitor Cst and the gate of the driving transistor M1 may be located in the same layer. Therefore, when manufacturing the array substrate, the same mask may be used to form the first electrode plate of the storage capacitor Cst and the gate of the driving transistor M1 in one same manufacturing process, and there may be no need to form separate masks for the first electrode plate of the storage capacitor Cst and the gate of the driving transistor M1. Therefore, the number of masks used in the manufacturing process of the array substrate may be reduced, the process cost may be reduced, and the process steps may be simplified.

In the initialization phase, when the first initialization transistor M4 is turned on, the initialization signal Vref may be transmitted to the first electrode plate of the storage capacitor Cst and the gate of the drive transistor M1 through the first initialization transistor M4, to initialize the first electrode plate of the storage capacitor Cst and the gate of the drive transistor M1. The second electrode plate of the storage capacitor Cst may be located in the second metal layer MC. Since the initialization signal line 2123 and the signal receiving layer may be respectively located in the second metal layer MC, the second electrode plate of the storage capacitor Cst, the signal receiving layer and the initialization signal line 2123 may be located in the same layer. Therefore, when manufacturing the array substrate, the second electrode plate of the storage capacitor Cst, the signal receiving layer and the initialization signal line 2123 may be formed in the same manufacturing process using the same mask, and there may be no need to form separate masks for the second electrode plate of the storage capacitor Cst, the signal receiving layer and the initialization signal line 2123. Therefore, the number of masks used in the manufacturing process of the array substrate may be reduced, the process cost may be reduced, and the process steps may be simplified.

Since the signal receiving layers and the initialization signal lines 2123 may be located in the same layer, there may be no need to connect the initialization signal lines 2123 to the signal receiving layers through holes. The processes may be simplified and the damage on the corresponding film layer induced by drilling may be avoided. By connecting the initialization signal lines 2123 to the signal receiving layers, the signal receiving layers of the virtual sub-pixels 221 may be used as the virtual signal lines 222. That is, the signal receiving layers may be used as a signal transmission carrier in parallel with the initialization signal lines 2123, thereby reducing the voltage drop on the initialization signal lines 2123 and improving the voltage uniformity of the initialization signal Vref output to each pixel circuit and the display uniformity.

As shown in FIG. 11, in another embodiment, the display panel 20 may include the substrate 23, the first metal layer M1, the second metal layer MC and the third metal layer M2. The first metal layer M1, the second metal layer MC, and the third metal layer M3 may be away from the substrate 23 sequentially. The initialization signal lines 2123 may be located in the third metal layer M2. One virtual sub-pixel 221 may include a signal receiving layer located in the third metal layer M2. Signal receiving layers of at least a part of the virtual sub-pixels 221 may be connected to the initialization signal lines 2123 to receive the initialization signal Vref transmitted in the initialization signal lines 2123.

Since the signal receiving layers and the initialization signal lines 2123 may be located in the same third metal layer M2, there may be no need to connect the initialization signal lines 2123 to the signal receiving layers through holes. The processes may be simplified and the damage on the corresponding film layer induced by drilling may be avoided. By connecting the initialization signal lines 2123 to the signal receiving layers, the signal receiving layers of the virtual sub-pixels 221 may be used as the virtual signal lines 222. That is, the signal receiving layers may be used as a signal transmission carrier in parallel with the initialization signal lines 2123, thereby reducing the voltage drop on the initialization signal lines 2123 and improving the voltage uniformity of the initialization signal Vref output to each pixel circuit and the display uniformity.

In one embodiment shown in FIG. 3, at least a portion of the virtual sub-pixels 221 in the virtual pixel region 22 may be used to receive at least two types of signals.

One virtual sub-pixel 221 may include at least one of the anode, the cathode 25 or the signal receiving layer in the above embodiment. Therefore, the virtual sub-pixel 221 may be connected to a target signal line, and the target signal line may include at least one of the first power signal line 2121, the second power signal line 2122, or the initialization signal line 2123. The virtual sub-pixel 221 may receive at least one of the first power signal PVDD, the second power signal PVEE, or the initialization signal Vref. When the virtual sub-pixel 221 is used to receive at least two types of electrical signals, the virtual sub-pixel 221 may be connected to at least two types of signal transmission lines 212, such that the voltage drop on the at least two types of signal transmission lines 212 may be reduced.

Compared with reducing the voltage drop on a single type of signal transmission lines 212, reducing the voltage drop on multiple types of signal transmission lines 212 may be more conducive to improving the display uniformity of the display panel 20. For example, reducing the voltage drop on the first power signal lines 2121 may only improve the voltage uniformity of the first power signal PVDD output to each pixel circuit; while reducing the voltage drop on the first power signal lines 2121 and the initialization signal lines 2123 may improve the voltage uniformity of the first power signal PVDD and the initialization signal Vref output to each pixel circuit. Compared to only reducing the voltage drop on the first power signal lines 2121, the initialization effect of each pixel circuit may be also improved, further improving the display uniformity of the display panel 20. Therefore, when the virtual sub-pixels 221 are used to receive at least two types of electrical signals, the display uniformity of the display panel 20 may be further improved.

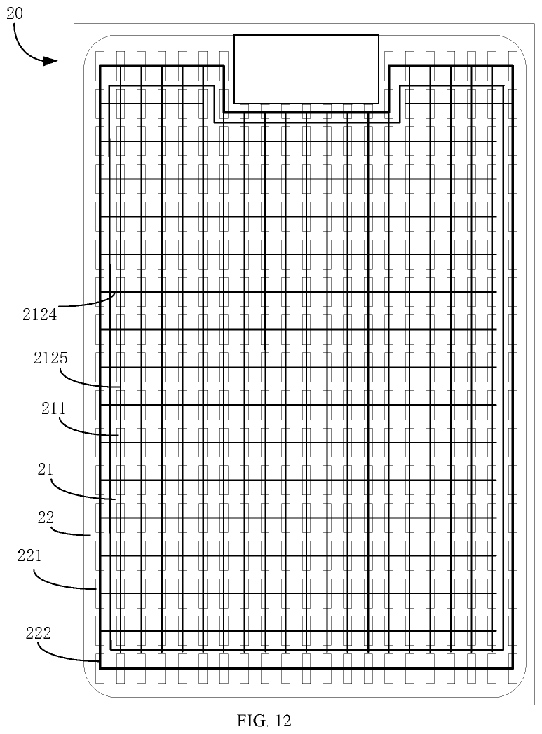

In one embodiment shown in FIG. 12 which is a planar structure of a display panel provided by the present embodiment, the plurality of signal transmission lines 212 may include first signal transmission sub-lines 2124 extending along a first direction and second signal transmission sub-lines 2125 extending along a second direction. First signal transmission sub-lines 2124 and second signal transmission sub-lines 2125 of a same type may be connected. The first signal transmission sub-lines 2124 may be connected to the virtual signal lines 222 extending along the second direction, and the second signal transmission sub-lines 2125 may be connected to the virtual signal lines 222 extending along the first direction. The first direction may intersect the second direction.

First signal transmission sub-lines 2124 and second signal transmission sub-lines 2125 of a same type may be connected. Therefore, the first signal transmission sub-lines 2124 and the second signal transmission sub-lines 2125 may be connected in parallel, and the resistance of the whole circuit formed by the first signal transmission sub-lines 2124 and the second signal transmission sub-lines 2125 may be reduced, to reduce the voltage drop on the first signal transmission sub-lines 2124 and the second signal transmission sub-lines 2125. Correspondingly, the voltage uniformity on the first signal transmission sub-lines 2124 and the second signal transmission sub-lines 2125 may be improved, improving the display uniformity of the display panel 20 in low gray scale.

As shown in FIG. 12, in one embodiment, the first signal transmission sub-lines 2124 may include first power signal sub-lines extending along the first direction, and the second signal transmission sub-lines 2125 may include second power signal sub-lines extending along the second direction. The first power signal sub-lines may be connected to the second power signal sub-lines. The first power signal sub-lines and the second power signal sub-lines may be used to transmit one of the first power signal PVDD and the second power signal PVEE respectively.

In one embodiment, the first power signal sub-lines and the second power signal sub-lines may be used to transmit the first power signal PVDD. Since the first power signal sub-lines may be connected to the second power signal sub-lines, the first power signal sub-lines and the second power signal sub-lines may be connected in parallel. The voltage drop on the first power signal sub-lines and the second power signal sub-lines may be reduced, improving the voltage uniformity of the first power signal PVDD output to each pixel circuit and the display uniformity of the display panel 20.

In another embodiment, the first power signal sub-lines and the second power signal sub-lines may be used to transmit the second power signal PVEE. Since the first power signal sub-lines may be connected to the second power signal sub-lines, the first power signal sub-lines and the second power signal sub-lines may be connected in parallel. The voltage drop on the first power signal sub-lines and the second power signal sub-lines may be reduced, improving the voltage uniformity of the second power signal PVEE output to each pixel circuit and the display uniformity of the display panel 20.

As shown in FIG. 12, in one embodiment, the first signal transmission sub-lines 2124 may include first initialization signal sub-lines 2123 extending along the first direction, and the second signal transmission sub-lines 2125 may include second initialization signal sub-lines extending along the second direction. The first initialization signal sub-lines may be connected to the second initialization signal sub-lines. The first initialization signal sub-lines and the second initialization signal sub-lines may be used to transmit the initialization signals Vref.

Since the first initialization r signal sub-lines may be connected to the second initialization signal sub-lines, the first initialization signal sub-lines and the second initialization signal sub-lines may be connected in parallel. The voltage drop on the first initialization signal sub-lines and the second initialization signal sub-lines may be reduced, improving the voltage uniformity of the initialization signal Vref output to each pixel circuit and the display uniformity of the display panel 20.

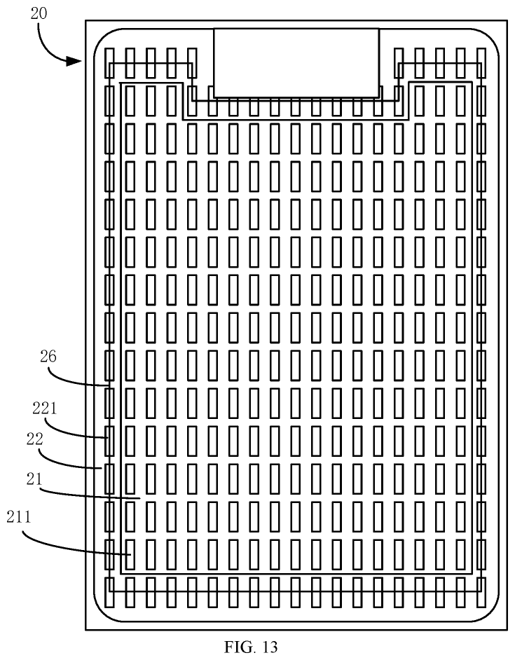

In another embodiment shown in FIG. 13 which is a planar structure of a display panel provided by the present embodiment, the display panel may include the substrate 23 and shielding signal lines 26 on one side of the substrate 23. The shielding signal lines 26 may be located in the virtual pixel region 22, and orthographic projections of the shielding signal lines 26 on the substrate 23 may overlap orthographic projections of at least a portion of the virtual sub-pixels 221 on the substrate 23. The shielding signal lines 26 may be connected to the plurality of signal transmission lines 212.

In one embodiment, the orthographic projections of the shielding signal lines 26 on the substrate 23 may completely overlap the orthographic projections of the virtual sub-pixels 221 on the substrate 23.

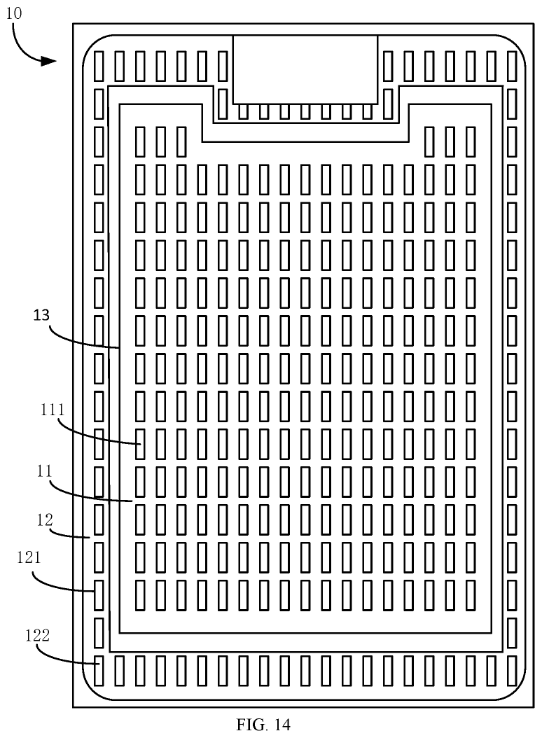

In related products as shown in FIG. 14 which is a planar structure of a display panel in existing technologies, the shielding signal lines (BSM signal lines) 13 may be connected to the driving circuit for transmitting corresponding signals to the pixel circuit. The shielding signal lines 13 in the display region 11 may block light. Further, the shielding signal lines 13 in the display region 11 may occupy a certain space, resulting in increased frame size.

In the present embodiment, the shielding signal lines 26 may be disposed in the virtual pixel region 22 and in the thickness direction of the virtual sub-pixels 221. Therefore, the shielding signal lines 26 may not occupy peripheral space, which is beneficial to achieving a narrow frame of the display panel 20. Further, the signal transmission lines 212 may be connected to the shielding signal lines 26, that is, the shielding signal lines 26 may be used as the virtual signal lines 222, and the signal transmission lines 212 may be connected in parallel with the shielding signal lines 26, thereby reducing the voltage drop on the signal transmission lines 212. The voltage uniformity of the signal transmission lines 212 may be improved, improving the display uniformity of the display panel 20.

As shown in FIG. 13, in one embodiment, the shielding signal lines 26 may be disposed around the display region 21.

In this embodiment, the shielding signal lines 26 may be arranged around the display region 21, such that each signal transmission line 212 in the display region 21 may be connected to corresponding shielding signal lines 26 more conveniently, thereby reducing the process difficulty.

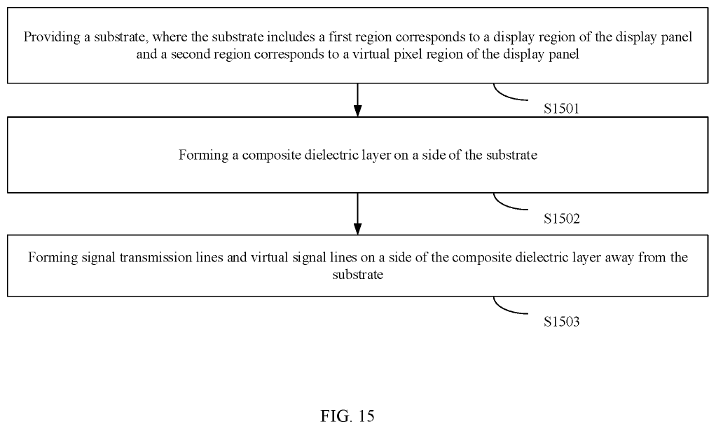

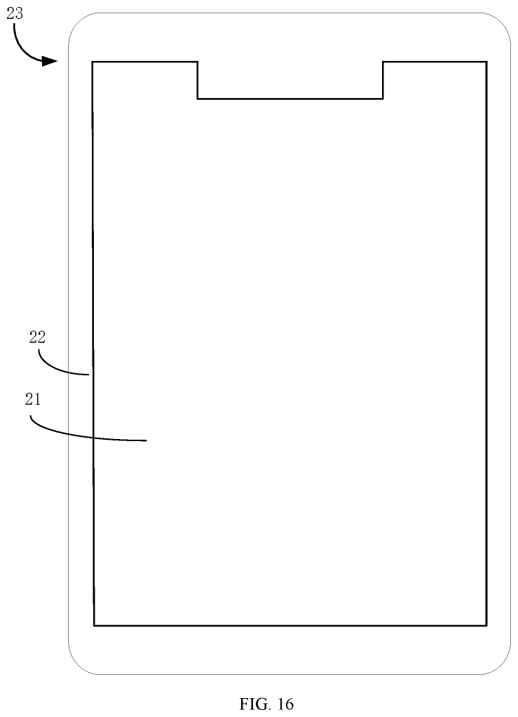

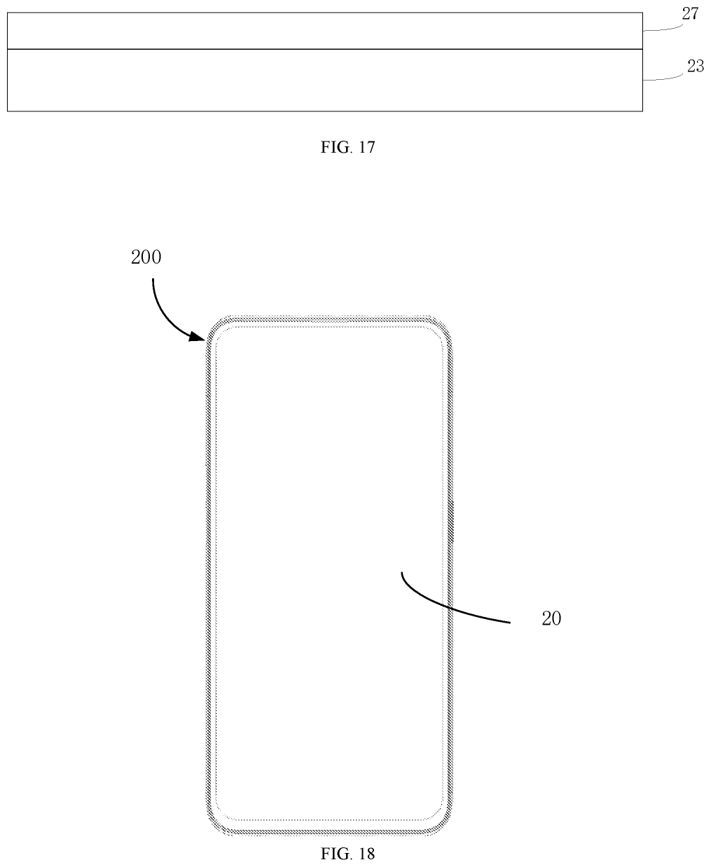

The present disclosure also provides a fabrication method of a display panel. As shown in FIG. 15 which is a flow chart of the fabrication method of a display panel, FIG. 16 is a structure of a substrate, and FIG. 17 is a cross-sectional view of a structure corresponding to a certain stage of the fabrication method, according to the present embodiment, the method may include S1501 to S1503.

In S1501: a substrate may be provided. The substrate may include a first region and a second region. The first region may correspond to a display region of the display panel, and the second region may correspond to a virtual pixel region of the display panel.

As shown in FIG. 16, the substrate 23 may provide support and protection to various film layers formed on the substrate. The substrate 23 may be a flexible substrate or a rigid substrate, which is not limited in the present disclosure.

In S1502, a composite dielectric layer may be formed on one side of the substrate.

As shown in FIG. 16, in one embodiment, the composite dielectric layer 27 may be formed on an upper surface of the substrate 23, and may include at least one insulation layer.

In S1503, signal transmission lines and virtual signal lines may be formed on a side of the composite dielectric layer away from the substrate. The orthographic projection of the signal transmission lines on the substrate may overlap the first region and extend to the second region. The orthographic projection of the virtual signal lines on the substrate may be located in the second region. At least a portion of the virtual signal lines may be connected to the signal transmission lines, and the signal transmission lines may include signal lines for connecting pixel circuits.

For the structure obtained in step S1503, the reference may be made to FIG. 2. The signal transmission lines 212 in the display region 21 may be connected to the virtual signal lines 222 in the virtual pixel region 22. The virtual signal lines 222 and the signal transmission lines 212 may be connected in parallel, thereby reducing the voltage drop of the signal transmission lines 212. The voltage uniformity of the signal transmission lines 212 may be improved, thereby improving the display uniformity of the display panel 20.

In the fabrication method of the display panel provided by the present disclosure, the signal transmission lines 212 and the virtual signal lines 222 may be formed on the side of the composite dielectric layer 27 away from the substrate 23. The orthographic projection of the signal transmission lines 212 on the substrate 23 overlaps with the first region and extends to the second region. The orthographic projection of the virtual signal lines 222 on the substrate 23 may be located in the second region, and at least a portion of the virtual signal lines 222 may be connected to the signal transmission lines 212. Therefore, the signal transmission lines 212 in the display region 21 may be connected to the virtual signal lines 222 in the virtual pixel region 22. Compared with the signal transmission lines 212, the resistance of the parallel transmission lines formed by the virtual signal lines 222 and the signal transmission lines 212 may be lower, thereby reducing the voltage drop of the signal transmission lines 212 and helping to maintain the voltage uniformity of the signal transmission line 212. The display uniformity of the display panel 20 may be improved.

As shown in FIG. 12, in one embodiment, the signal transmission lines may include first signal transmission sub-lines and second signal transmission sub-lines. Forming the signal transmission lines on the side of the composite dielectric layer away from the substrate, may include: forming the first signal transmission sub-lines extending along the first direction and the second signal transmission sub-lines extending along the second direction on the side of the substrate. The first direction intersects the second direction, and the orthographic projections of the first signal transmission sub-lines 2124 and the second signal transmission sub-lines 2125 on the substrate 23 may respectively overlap with the first region and extend to the second region. The first signal transmission sub-lines 2124 and the second signal transmission sub-lines 2125 may be respectively connected to the virtual signal lines 222.

Since the first initialization signal sub-lines may be connected to the second initialization signal sub-lines, the first initialization signal sub-lines and the second initialization signal sub-lines may be connected in parallel. The voltage drop on the first initialization signal sub-lines and the second initialization signal sub-lines may be reduced, improving the voltage uniformity of the initialization signal Vref output to each pixel circuit and the display uniformity of the display panel 20.

In one embodiment shown in FIG. 6 and FIG. 7, the signal transmission lines may include first power signal lines. Forming the signal transmission lines on the side of the composite dielectric layer away from the substrate may include: forming the first power signal lines in the first region of the substrate. The fabrication method of the display panel may also include: forming an anode layer on the side of the composite dielectric layer away from the substrate. The orthographic projection of the anode layer 24 on the substrate 23 may be at least partially located in the second region, and the anode layer 24 may be connected to the first power signal lines 2121.

The anode layer 24 may be a conductive layer and may be able to transmit the first power signal PVDD. By forming the anode layer 24 on the side of the composite dielectric layer 27 away from the substrate 23 and making the orthographic projection of the anode layer 24 on the substrate 23 at least partially located in the second region, the anode layer 24 may be formed in the virtual pixel region 22. The anode layer 24 may be connected to the first power signal lines 2121. Therefore, the anodes of the virtual sub-pixels 221 may be used as a signal transmission carrier, and the first power signal lines 2121 may be connected in parallel with the anodes of the virtual sub-pixels 221. Correspondingly, the voltage drop on the first power signal lines 2121 may be reduced, improving the voltage uniformity of the first power signal PVDD output to each pixel circuit, thereby improving display uniformity.

As shown in FIG. 13, in one embodiment, the method may further include: forming shielding signal lines on the side of the composite dielectric layer 27 away from the substrate 23. The orthographic projection of the shielding signal lines 26 on the substrate 23 may be located in the second region, and may overlap orthographic projections of at least a portion of the virtual sub-pixels 221 on the substrate 23. The shielding signal lines 26 may be connected to the signal transmission lines 212.

In the present embodiment, the shielding signal lines 26 may be formed on the side of the composite dielectric layer 27 away from the substrate 23. The orthographic projection of the shielding signal lines 26 on the substrate 23 may be located in the second region. Therefore, the shielding signal lines 26 may be formed in the virtual pixel region 22 and in the thickness direction of the virtual sub-pixels 221. Therefore, the shielding signal lines 26 may not occupy peripheral space, which is beneficial to achieving a narrow frame of the display panel 20. Further, the signal transmission lines 212 may be connected to the shielding signal lines 26, that is, the shielding signal lines 26 may be used as the virtual signal lines 222, and the signal transmission lines 212 may be connected in parallel with the shielding signal lines 26, thereby reducing the voltage drop on the signal transmission lines 212. The voltage uniformity of the signal transmission lines 212 may be improved, improving the display uniformity of the display panel 20.

Although various steps in the flowchart of the accompanying drawings are shown in sequence as indicated by arrows, these steps are not necessarily performed in the order indicated by arrows. Unless explicitly stated in the present disclosure, there is no strict order restriction on the execution of these steps, and these steps may be executed in other orders. Moreover, at least some of the steps in the drawings may include multiple steps or stages. These steps or stages are not necessarily executed at the same time, but may be executed at different times. These steps or stages are not necessarily to be performed sequentially, but may be performed in turn or alternately with other steps or at least part of the steps or stages in other steps.

The present disclosure also provides a display device. In one embodiment shown in FIG. 18 which is a top view of the display device, the display device 200 may include a display panel provided by various embodiments of the present disclosure.

The display device 200 in various embodiments may be an OLED display device, an electronic paper, a cell phone, a tablet, a television, a monitor, a laptop, a digital album, a navigator, a wearable device, an internet of things device, or other products or parts with display functions.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising a display region and a virtual pixel region around the display region, wherein:
the display region includes display sub-pixels, and a plurality of signal transmission lines is disposed in the display region for connecting pixel circuits;
the virtual pixel region includes virtual sub-pixels and a plurality of virtual signal lines connected to the virtual sub-pixels; and
at least a portion of the plurality of the virtual signal lines is connected to the plurality of signal transmission lines.

2. The display panel according to claim 1, wherein:
types of the plurality of signal transmission lines include at least one of first power signal lines, second power signal lines, or initialization signal lines.

3. The display panel according to claim 2, wherein:
the plurality of virtual signal lines is respectively connected to signal transmission lines of a same type among the plurality of signal transmission lines.

4. The display panel according to claim 2, wherein:
the plurality of virtual signal lines is respectively connected to signal transmission lines of different types among the plurality of signal transmission lines.

5. The display panel according to claim 2, further including a substrate and an anode layer on a side of the substrate, wherein:
the anode layer includes anodes of the virtual sub-pixels; and
the anodes of at least a portion of the virtual sub-pixels are connected to the first power signal lines to receive a first power signal transmitted by the first power signal lines.

6. The display panel according to claim 5, wherein:
the anode of each virtual sub-pixel is connected to each other.

7. The display panel according to claim 5, wherein:
the virtual pixel region includes a plurality of irregular-shaped regions;
the anode layer includes an irregular-shaped sub-anode layer located in each of the plurality of irregular-shaped regions, and the irregular-shaped sub-anode layer includes an anode of one corresponding virtual sub-pixel in the irregular-shaped region;
irregular-shaped sub-anode layers are connected to the first power signal lines and are used to receive the first power signal transmitted by the first power signal lines.

8. The display panel according to claim 2, further including a substrate and a cathode layer on a side of the substrate, wherein:
the cathode layer includes cathodes of the virtual sub-pixels; and
the cathodes of at least a portion of the virtual sub-pixels are connected to the second power signal lines to receive a second power signal transmitted by the second power signal lines.

9. The display panel according to claim 1, further including a substrate, wherein:
the plurality of virtual signal lines and the virtual sub-pixels are located on a same side of the substrate, and a width of an orthographic projection of the virtual sub-pixels on the substrate is larger than or equal to a width of an orthographic projection of the plurality of virtual signal lines on the substrate.

10. The display panel according to claim 2, further including a substrate, a first metal layer, a second metal layer, and a third metal layer, wherein:
the first metal layer, the second metal layer and the third metal layer are sequentially away from the substrate;
the initialization signal lines are located in the second metal layer;
one virtual sub-pixel includes a signal receiving layer, and the signal receiving layer is located in the second metal layer; and
signal receiving layers of at least a portion of the virtual sub-pixels are connected to the initialization signal lines to receive an initialization signal transmitted by the initialization signal lines.

11. The display panel according to claim 2, further including a substrate, a first metal layer, a second metal layer, and a third metal layer, wherein:
the first metal layer, the second metal layer and the third metal layer are sequentially away from the substrate;
the initialization signal lines are located in the third metal layer;
one virtual sub-pixel includes a signal receiving layer, and the signal receiving layer is located in the third metal layer; and
signal receiving layers of at least a portion of the virtual sub-pixels are connected to the initialization signal lines to receive an initialization signal transmitted by the initialization signal lines.

12. The display panel according to claim 2, wherein:
at least a portion of the virtual sub-pixels is used to receive two types of electric signals.

13. The display panel according to claim 2, wherein:
the plurality of signal transmission lines include first signal transmission sub-lines extending along a first direction and second signal transmission sub-lines extending along a second direction;
the first signal transmission sub-lines and the second signal transmission sub-lines of the same type are connected;
the first signal transmission sub-lines are connected to virtual signal lines extending along the second direction among the plurality of virtual signal lines;
the second signal transmission sub-lines are connected to virtual signal lines extending along the first direction among the plurality of virtual signal lines; and
the first direction and the second direction intersect.

14. The display panel according to claim 13, wherein:
the first signal transmission sub-lines include first power signal sub-lines extending along the first direction;
the second signal transmission sub-lines include second power signal sub-lines extending along the second direction,
the first power signal sub-lines are connected to the second power signal sub-lines; and
the first power signal sub-lines and the second power signal sub-lines are respectively used to transmit one of the first power signal and the second power signal.

15. The display panel according to claim 13, wherein:
the first signal transmission sub-lines include first initialization signal sub-lines extending along the first direction;
the second signal transmission sub-lines include second initialization signal sub-lines extending along the second direction,
the first initialization signal sub-lines are connected to the second initialization signal sub-lines; and
the first initialization signal sub-lines and the second initialization signal sub-lines are respectively used to transmit initialization signals.

16. The display panel according to claim 1, further including a substrate and shielding signal lines on a side of the substrate, wherein:
the shielded signal lines are located in the virtual pixel region, and orthographic projections of the shielded signal lines on the substrate overlap orthographic projections of at least a portion of the virtual sub-pixels on the substrate; and
the plurality of signal transmission lines is connected to the shielding signal lines.

17. The display panel according to claim 16, wherein:
the shielding signal lines are disposed around the display region.

18. A fabrication method of a display panel, comprising:
providing a substrate, wherein the substrate includes a first region corresponds to a display region of the display panel and a second region corresponds to a virtual pixel region of the display panel;
forming a composite dielectric layer on a side of the substrate; and
forming signal transmission lines and virtual signal lines on a side of the composite dielectric layer away from the substrate, wherein:
orthographic projections of the signal transmission lines on the substrate overlap with the first region and extend to the second region,
orthographic projections of the virtual signal lines on the substrate are located in the second region;
at least a portion of the virtual signal lines is connected to the signal transmission lines; and
the signal transmission lines include signal lines for connecting pixel circuits.

19. The method according to claim 18, wherein:
the signal transmission lines include first signal transmission sub-lines and second signal transmission sub-lines; and
forming the signal transmission lines and virtual signal lines on the side of the composite dielectric layer away from the substrate includes:
forming the first signal transmission sub-lines extending along a first direction and the second signal transmission sub-lines extending along a second direction, wherein:
the first direction intersects the second direction;
orthographic projections of the first signal transmission sub-lines and the second signal transmission sub-lines on the substrate respectively overlap with the first region and extend to the second region, and
the first signal transmission sub-lines and the second signal transmission sub-lines are respectively connected to the virtual signal lines.

20. A display device, comprising a display panel, wherein:
the display panel includes a display region and a virtual pixel region around the display region:
the display region includes display sub-pixels, and a plurality of signal transmission lines are disposed in the display region for connecting pixel circuits;
the virtual pixel region includes virtual sub-pixels and a plurality of virtual signal lines connected to the virtual sub-pixels; and
at least a portion of the plurality of the virtual signal lines is connected to the plurality of signal transmission lines.
